(19) United States
(12) Patent Application Publication
(10) Pub. No.: US 2014/0273330 A1
(43) Pub. Date: Sep. 18, 2014

(54) METHOD OF FORMING SINGLE SIDE TEXTURED SEMICONDUCTOR WORKPIECES

(71) Applicant: VARIAN SEMICONDUCTOR EQUIPMENT ASSOCIATES, INC., Gloucester, MA (US)

(72) Inventors: Vikram M. Bhosle, N.Reading, MA (US); Christopher E. Dube, Lexington, MA (US); Deepak A. Ramappa, Somerville, MA (US)

(73) Assignee: Varian Semiconductor Equipment Associates, Inc., Gloucester, MA (US)

(21) Appl. No.: 13/795,726

(22) Filed: Mar. 12, 2013

(51) Int. Cl. H01L 31/0236

(52) U.S. Cl. CPC H01L 31/02366
USPC 438/71

(57) ABSTRACT

Methods of creating a workpiece having a smooth side and a textured side are disclosed. In some embodiments, a first side of a workpiece is doped, using ion implantation or diffusion, to create a doped layer. This doped layer of the first side may be more resistant to chemical treatment than the second side of the workpiece. This allows the second side of the workpiece to be textured without capping or otherwise protecting the doped first side, even though the doped layer of the first side physically contacts the chemical treatment. In some embodiments, a p-type dopant is used to create the doped layer. In some embodiments, the workpiece is processed to form a solar cell.

Embodiments of the present invention relate to methods to forming a single side textured workpiece, and more particularly, a single side textured solar cell.

### BACKGROUND

There are instances where it is beneficial to create a semiconductor workpiece having one smooth side and one textured side. For example, it may be desirable to create a solar cell where the front side, or the surface which receives solar energy, is textured to maximize its surface area. Meanwhile, it may also be desirable to have the opposite side, or back side, of the solar cell be as smooth as possible to maximize its reflective properties. A smooth back side may also result in higher short circuit current density (J_{sc}) and higher open circuit voltage (V_{oc}).

Traditionally, to create a workpiece having these characteristics, a large number of process steps were required. FIG. 1 shows a traditional process flow for a solar cell that is textured on one side and smooth on the opposite side. This particular process is used to create a PERT (passivated emitter, rear totally diffused) solar cell. Similar processes may be used to create other types of solar cells, such as IBC (interdigitated back contact), PERL (passivated emitter, rear locally diffused) and selective emitter solar cells.

First, as shown in step 100, a saw damage etch (SDE) is performed to create a smooth surface. In some embodiments, this may be performed on both sides of the solar cell. The back surface is then capped with a protective layer, such as silicon nitride (SiN) as shown in step 101. The workpiece is then textured, as shown in step 102. This may be performed by exposing the workpiece to a chemical treatment, such as an acid or base solution. This solution etches the unexposed front side of the workpiece, thereby creating the desired texture on the front side. The back side is not affected, as the SiN is impermeable to the solution. The protective layer is then removed, using a process which is effective in removing the SiN, as shown in step 103. Once the texture has been created, the workpiece can be processed to create a solar cell. In step 104, a boron based compound, such as boron tribromide (BBr₃) is diffused into the workpiece. This creates p-type conductivity on the surfaces of both the front side and the back side of the workpiece. This process also creates borosilicate glass (BSG), which must be etched from both the front side and back side, as shown in step 105. In addition, the boron has to be removed from one of the surfaces, as only one surface may require a p-type conductivity, Thus, a boron layer removal step 106 is performed on one of the sides of the workpiece, which may be the front side in some embodiments. The side having the p-type conductivity (i.e. the back side) is then capped with a protective layer, as shown in step 107. A second diffusion step 108 is then performed, using a species such as phosphoryl chloride (POCl₃), to create an n-type conductivity layer on the opposite side, which may be the front side of the workpiece in some embodiments. As was done before, an etching step 109 must be performed. In this step, the phosphosilicate glass (PSG) is removed from one surface. The protective layer can then be removed from the other side, as shown in step 110. Once the workpiece has been properly doped, the surfaces of the workpiece are then treated. The front side of the workpiece may receive a passivation layer, as shown in step 111. This may be an oxide or nitride layer. An antireflective coating (ARC) is then applied to the front side, as shown in step 112. These passivation and ARC steps 111, 112, respectively, are then repeated for the back side in steps 113, 114. After this, the workpiece may receive laser patterning, as shown in step 115 and screen printing (SP), metallization and a firing step 116 are performed.

While other processes are also possible, this representative process illustrates that several steps are dedicated to the texturing of one side while leaving the other side unaffected. Specifically, the capping step 101, texture step 102, and protecting layer removal step 103 are all specifically required to protect one side of the workpiece while the other side is being textured. The additional handling of the workpieces during these steps may lead to significant workpiece yield loss, due to breakage, contamination or other factors.

Therefore, it would be beneficial if there was a more efficient method of providing texture to one side of a workpiece while not affecting the other side of the workpiece.

### SUMMARY

Methods of creating a workpiece having a smooth side and a textured side are disclosed. In some embodiments, a first side of a workpiece is doped, using ion implantation or diffusion, to create a doped layer. This doped layer of the first side may be more resistant to chemical treatment than the second side of the workpiece. This allows the second side of the workpiece to be textured without capping or otherwise protecting the doped first side, even though the doped layer of the first side physically contacts the chemical treatment. In some embodiments, a p-type dopant is used to create the doped layer. In some embodiments, the workpiece is processed to form a solar cell.

In one embodiment, a method of processing a workpiece comprises creating a doped layer in a first side of the workpiece; subjecting the workpiece to a chemical treatment to texture the workpiece, wherein a second side, opposite the first side, and the doped layer of the first side physically contact the chemical wherein only the second side becomes textured; and processing the second side of said workpiece.

In another embodiment, regions of a side may be textured, while other regions on that side are left smooth. In one embodiment, a method of processing a workpiece comprises creating a doped layer in a region of a first side of the workpiece that is less than an entirety of the first side; subjecting the workpiece to a chemical treatment to texture the workpiece, wherein the doped layer of the first side physically contacts the chemical and the region does not become textured; and applying a metallization layer to the region.

In another embodiment, a method of creating a solar cell is disclosed. This method comprises implanting ions of a first dopant in a first side of a workpiece to create a doped layer; thermally treating the workpiece after the implant of the first dopant; subjecting the workpiece to a chemical treatment, after the thermal treating step, wherein a second side, opposite the first side, and the doped layer of the first side physically contact the chemical wherein only the second side becomes textured; and implanting ions of a second dopant in the second side.

### BRIEF DESCRIPTION OF THE FIGURES

For a better understanding of the present disclosure, reference is made to the accompanying drawings, which are incorporated herein by reference and in which:

FIG. 1 shows a process flow for creating a solar cell according to the prior art;

FIG. 2 shows a process flow for creating a semiconductor workpiece having a textured surface and a smooth surface;

FIG. 3 shows a process flow for creating a solar cell according to a first embodiment;

FIG. 4 shows a process flow for creating a solar cell according to a second embodiment;

FIG. 5 shows a process flow for creating a solar cell according to a third embodiment; and

FIG. 6 shows a process flow for creating a semiconductor workpiece having a surface having smooth regions and textured regions.

### DETAILED DESCRIPTION

As described above, providing texture to one side of a semiconductor workpiece requires the use of several dedicated steps. While the process of FIG. 1 was described in connection with PERT solar cells, these dedicated steps are needed for the manufacture of IBC and other solar cells. In fact, these steps are needed for any workpiece where only side is to be textured.

Doped semiconductor surfaces, such as semiconductor surfaces doped with Group III elements, including boron and gallium, may exhibit more resistance to traditional etching processes than undoped surfaces. This phenomenon may be advantageously used to streamline the manufacturing process for workpieces which require only one textured side, such as solar cells.

FIG. 2 represents a general process flow that can be used to create a workpiece having a first smooth side and a second textured side. In this process, a first side of a workpiece is polished, such as by an SDE process as shown in step 200. In some embodiments, both sides of the workpiece are polished in step 200. The first side of the workpiece is then processed so as to form a doped layer, as shown in step 201. In some embodiments, this may be a p-type doped layer, while in other embodiments, a n-type doped layer may be formed. This may be achieved using ion implantation, furnace diffusion, diffusion pastes, or other methods. The workpiece is then subjected to a chemical treatment, as shown in step 202, which serves to texture the second side of the workpiece that is not doped in step 201. This step is performed such that the first and second sides of the workpiece both physically contact the chemical treatment. In other words, the doped layer on the first side directly contacts the chemical and there is no protective layer applied to the first side prior to the chemical treatment 202. This second textured side can then be processed in accordance with the particular device that is being created, as shown in step 203. There are no limitations on the further processing that may be performed on either side of the workpiece after the steps of FIG. 2 have been completed.

Several specific embodiments which advantageous benefit from the etch resistance of doped surfaces are described below. However, it is noted that these embodiments are not intended to be limiting, rather they are illustrative of the application of this concept to various manufacturing processes.

FIG. 3 shows a first manufacturing process flow for a PERT solar cell, using many of the same process steps as were used in FIG. 1. In other words, this process utilizes diffusion to dope both the front and back sides of the workpiece. Steps which are unchanged from the prior art have been labeled with the same reference designators as used in FIG. 1. In FIG. 3, following the SDE polishing step 100, p-type diffusion 301 is performed. Note that this step may be identical to step 104 of FIG. 1, or may employ a different p-type dopant. As described above, this creates a p-type layer in both the second side (i.e. the front) and the first side (i.e. the back) of the workpiece, and also results in the formation of borosilicate on the workpiece. As was described above, the BSG is removed in step 105 and the p-type layer is removed from the second side in step 106. At this point in the process, the first side of the workpiece has a p-type doped layer, while the second side is now undoped. The workpiece is then subjected to texturing step 102. As described above, this step is performed such that the first and second sides of the workpiece both physically contact the chemical treatment. In other words, the doped layer on the first side directly contacts the chemical. However, since the first side has already been doped by p-type dopants, it is resistant to the chemical treatment, and remains smooth without the need to cap it with a protective coating, as was done in step 101 of FIG. 1. After the texturing step 102 is completed, the workpiece is processed in accordance with steps 107-116 of FIG. 1. Note that by performing the p-type diffusion 200 prior to the texturing step 102, the capping step 101 and capping removal step 103 can be eliminated.

FIG. 4 is a manufacturing process flow for a PERT solar cell, similar to FIG. 3, but employing single sided diffusion. In FIGS. 1 and 3, the diffusion may be performed using a diffusion furnace, where dopants are diffused into both sides of the workpiece. In FIG. 4, a different diffusion technique, such as a diffusion paste, may be employed. Pastes can be selectively applied, so that the paste is only applied to the side of interest. In this way, only one side becomes doped and a p-type doped layer is only created on one side. Thus, after the SDE polishing step 100, a paste containing a p-type dopant is applied to the first side (i.e. the back) of the workpiece, as shown in step 400, to create a p-type doped layer in the first side. Because the dopant is applied only to one side, the BSG glass only develops on this side and the BSG etch step 401 is only performed on the first side. The workpiece is then textured in step 102, as described above. As described above, this step is performed such that the first and second sides of the workpiece both physically contact the chemical treatment. In other words, the doped layer on the first side directly contacts the chemical. Afterwards, a paste containing an n-type dopant is applied to the second side (i.e. the front) in step 402. The PSG glass is then removed from the second side in step 403. The remaining steps 111-116 are as described in the prior art. Thus, this process eliminates three additional steps by utilizing diffusion techniques that only affect one side of the workpiece.

FIG. 5 shows a third embodiment of a manufacturing process flow. In this embodiment, the workpiece becomes doped through the use of ion implantation, rather than diffusion. Following the SDE polish step 101, a p-type implant is performed on the first side (i.e. the back) of the workpiece, as shown in step 500. This implant may comprise a p-type dopant such as boron or gallium. The ion implant system used in step 500 may be any ion implant system, including a plasma deposition (PLAD) or beamline system. After ion implantation, the workpiece is thermally treated in step 501 to anneal the damage caused by the ion implant. This thermal treatment recrystallizes the first side and activates the dopant in the first side of the workpiece, thereby creating a p-type doped layer in the first side of the workpiece. The workpiece can then be textured in step 102 using the techniques described above. As described above, this step is performed such that the first and second sides of the workpiece both physically contact the chemical treatment. In other words, the doped layer on the first side directly contacts the chemical. After texturing, the second side (i.e. the front) of the workpiece is implanted with an n-type dopant, such as phosphorus or arsenic in step 502. The workpiece is then thermally treated again in step 503 to anneal the second side of the workpiece. If the thermal treatment is performed in the presence of oxygen, the second side will be annealed and an oxide layer will simultaneously be grown on that second surface. This oxide layer may serve as a passivation layer, thereby eliminating step 111 used on the previous embodiments. The remaining steps 112-116 are as described above.

While FIGS. 3-5 show specific process flows to create particular types of solar cells, the disclosure is not limited to these embodiments. For example, other embodiments based on FIG. 5 are possible. In one embodiment, the first side (i.e. the back) of the workpiece is polished, as shown in step 100, a p-type dopant is implanted and thermally treated as shown in steps 500, 501, respectively, and the workpiece is then textured, as shown in shown 102. As described above, this step is performed such that the first and second sides of the workpiece both physically contact the chemical treatment. In other words, the doped layer on the first side directly contacts the chemical. After this, process steps different from those shown in FIG. 5 may be executed to create a different configuration of solar cell. In another embodiment, multiple implants may be performed on the first side of the workpiece prior to the thermal treatment step 501. For example, an IBC solar cell may be created in this way.

In some embodiments, p-type doped semiconductors display a greater resistance to etching than n-type doped semiconductors. In this embodiment, the first side may be p-type doped, such as by ion implantation, as shown in FIG. 5. However, in another embodiment, before the thermal treatment and texture steps 501, 102 respectively, the second side of the workpiece may be ion implanted with an n-type dopant. The workpiece is then thermally treated to anneal the implant damage and the texturing step 102 is performed. The chemical solution is more effective in etching material from the n-type doped front side, thereby texturing that n-type doped second surface without affecting the p-type doped first side.

Furthermore, while p-type doped semiconductors may exhibit greater resistance to etching, in some embodiments, the resistance of n-type doped semiconductors may be sufficient to resist the particular etch that occurs. Therefore, in any of the process flows described above, the workpiece may be n-type doped prior to thermal treatment and etching. Specifically, the process described in FIG. 2 may be applicable to both n-type and p-type dopants.

Furthermore, while FIGS. 3-5 all depict a p-type doping step prior to texturing and an n-type doping step after texturing, the application is not limited to this embodiment. For example, a layer of a first dopant may be formed on a first side, and this layer may be thermally treated to activate the first dopant. The workpiece may then be subjected to chemical processing so as to texture the second side of the workpiece. A layer of a second dopant may be formed on the second side. In some embodiments, a second thermal treatment is performed after the layer of second dopant is formed. The first and second dopants may each be either a p-type dopant or an n-type dopant.

While the above embodiments are described in connection with creating one polished side and one textured side of a workpiece, the disclosure is not limited to this. For example, this technique can be used to create one side of a workpiece having both smooth portions and textured portions. This may be useful, for example, in a solar cell having a metallization layer on the front side.

FIG. 6 shows a process flow of this embodiment. First, regions of a first side of the workpiece are doped by a p-type dopant, such as boron or gallium, or an n-type dopant, such as phosphorus, in step 600. This may be done in various ways, such as, for example, with a patterned ion implant, or a screen printed paste. Thus, less than the entirety of the first side of the workpiece is doped in this manner. The workpiece is then textured in step 601, such as by using an etch bath. This step is performed such that the first side of the workpiece physically contacts the chemical treatment. In other words, there is no protective layer applied to the first side prior to the chemical treatment. In other words, the doped layer on the first side directly contacts the chemical. As described above, the previous doped regions are more resistant to this etching process and remain smooth, while the undoped portions of the first surface become textured. In some embodiments, as shown in step 602, a metallization pattern may be applied to the previously p-type doped smooth portions. This may allow the metal layer to achieve better contact with the semiconductor workpiece, while increasing the surface area of the rest of the front side of the workpiece.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A method of processing a workpiece, comprising:
creating a doped layer in a first side of said workpiece;
subjecting said workpiece to a chemical treatment to texture said workpiece, wherein a second side, opposite said first side, and said doped layer of said first side physically contact said chemical wherein only said second side becomes textured; and
processing said second side of said workpiece.

2. The method of claim 1, wherein said doped layer comprises a p-type doped layer.

3. The method of claim 1, wherein said creating step comprises diffusing a p-type dopant into said first side.

4. The method of claim 3, further comprising removing a glass layer from said first side after said diffusing step and before said subjecting step.

5. The method of claim 1, wherein said creating step comprises:
diffusing a p-type dopant into said first side and said second side; and
removing said p-type dopant from said second side.

6. The method of claim 5, further comprising removing a glass layer from said first side and said second side after said diffusing step and before said subjecting step.

7. The method of claim 2, wherein said processing step comprises creating an n-type doped layer in said second side.

8. A method of processing a workpiece, comprising:
creating a doped layer in a region of a first side of said workpiece that is less than an entirety of said first side;
subjecting said workpiece to a chemical treatment to texture said workpiece, wherein said doped layer of said first side physically contacts said chemical and said region does not become textured; and
applying a metallization layer to said region.

9. The method of claim 8, wherein said creating step comprises screen printing a paste on said region.

10. The method of claim 8, wherein said creating step comprises implanting ions into said region.

11. A method of creating a solar cell comprising:
implanting ions of a first dopant in a first side of a workpiece to create a doped layer;
thermally treating said workpiece after said implant of said first dopant;
subjecting said workpiece to a chemical treatment, after said thermal treating step, wherein a second side, opposite said first side, and said doped layer of said first side physically contact said chemical wherein only said second side becomes textured; and
implanting ions of a second dopant in said second side.

12. The method of claim 11, wherein a second thermal treatment step is performed after said implanting of said second dopant.

13. The method of claim 12, wherein said second thermal treatment step is performed in the presence of oxygen to create an oxide layer on said second side.

14. The method of claim 11, wherein said implanting of said second dopant is performed before said thermal treating step.

15. The method of claim 11, wherein said first dopant comprises a p-type dopant and said second dopant comprises an n-type dopant.
